(19) United States
(12) Patent Application Publication
(10) Pub. No.: US 2018/0169649 A1
(43) Pub. Date: Jun. 21, 2018

(54) LIQUID MEDICINE DISCHARGE DEVICE AND LIQUID MEDICINE DROPPING DEVICE

(71) Applicant: TOSHIBA TEC KABUSHIKI KAISHA, Tokyo (JP)

(72) Inventors: Shuhei YOKOYAMA, Mishima Shizuoka (JP); Satoshi KAIHO, Yokohama Kanagawa (JP); Seiya SHIMIZU, Numazu Shizuoka (JP); Hiroyuki KUSHIDA, Odawara Kanagawa (JP)

(21) Appl. No.: 15/694,974

(22) Filed: Sep. 4, 2017

(30) Foreign Application Priority Data
Dec. 21, 2016 (JP) 2016-247696

(51) Int. Cl. B01L 3/00; F04B 43/04

(52) U.S. Cl. CPC B01L 3/502; F04B 43/046; B01L 2400/0487; H01L 41/18; B01L 2300/12; B01L 2400/0633; F04B 2203/0402; B01L 2300/0829

(57) ABSTRACT

According to one embodiment, a liquid medicine discharge device includes a nozzle plate including a nozzle from which a liquid medicine can be discharged, a pressure chamber structure having an outlet on a first surface side and an inlet on a second surface side and a pressure chamber in fluid communication with the nozzle via the outlet on the first side, a liquid holding container on the second surface and in fluid communication with the pressure chamber via the inlet on the second surface, and an actuator configured to cause the liquid medicine to be ejected from the nozzle by changing a pressure in the pressure chamber and including a piezoelectric element formed of a lead-free material.

### CROSS-REFERENCE TO RELATED APPLICATION

This application is based upon and claims the benefit of priority from Japanese Patent Application No. 2016-247696, filed Dec. 21, 2016, the entire contents of which are incorporated herein by reference.

### FIELD

Embodiments described herein relate generally to a liquid medicine discharge device and a liquid medicine dropping device.

### BACKGROUND

Liquid dispensing in a range of microliters (μL) to picoliters (pL) is often used in pharmaceutical and biological research and development, medical diagnosis and examination, or agricultural experiments.

For example, in studying a dose-response experiment, compounds are prepared at many different concentrations in wells or the like of a microplate to determine an effective concentration using a liquid medicine dropping device. The liquid medicine dropping device includes an attachable and detachable liquid medicine discharge device.

In a dose-response experiment, various types of liquid medicine are used. In addition, for a use in medical and biological fields, a liquid medicine discharge device is often disposable to prevent contamination. Therefore, a large number of disposable devices are wasted.

In an ink jet printer, a piezoelectric material, PZT (Pb(Zr,Ti)O₃:lead zirconate titanate), is generally used for a piezoelectric element in an actuator for discharging liquid.

For use in the medical and biological fields, such as a dose response experiment, disposable liquid discharging devices are used. These disposable devices are detached and exchanged a number of times daily, and thus a large number of liquid medicine discharge devices must be disposed. Therefore, when a material containing lead is used for an actuator in the liquid medicine dropping device like the ink jet printer, the environmental load in the disposal process of the liquid medicine dropping device is much larger than that of the ink jet printer.

### BRIEF DESCRIPTION OF THE DRAWINGS

FIG. 1 is a schematic perspective view of a liquid medicine dropping device having a liquid medicine discharge device according to an embodiment.

FIG. 2 is a top view of a liquid medicine discharge device.

FIG. 3 is a bottom view of a liquid medicine discharge device.

FIG. 4 is a cross-sectional view taken along the line F4-F4 of FIG. 2.

FIG. 5 is a plan view of a liquid medicine discharge array of a liquid medicine discharge device.

FIG. 6 is a cross-sectional view taken along the line F6-F6 of FIG. 5.

FIG. 7 is a longitudinal sectional view of a peripheral structure of a nozzle of a liquid medicine discharge device.

FIG. 8 is a view of an example of a lead-free material of an actuator of a liquid medicine discharge device.

FIG. 9 is a view of another example of a lead-free material of an actuator of a liquid medicine discharge device.

FIG. 10 is a view of another example of a lead-free material of an actuator of a liquid medicine discharge device.

### DETAILED DESCRIPTION

In general, according to one embodiment, a liquid medicine discharge device includes a nozzle plate including a nozzle from which a liquid medicine can be discharged, a pressure chamber structure having an outlet on a first surface side and an inlet on a second surface side and a pressure chamber in fluid communication with the nozzle via the outlet on the first side, a liquid holding container on the second surface and in fluid communication with the pressure chamber via the inlet on the second surface, and an actuator configured to cause the liquid medicine to be ejected from the nozzle by changing pressure in the pressure chamber and including a piezoelectric element formed of a lead-free material.

Hereinafter, an example embodiment will be described with reference to the drawings. In addition, each of the drawings is a schematic drawing for understanding example embodiment and the principle thereof, and there are parts of which the shape, the dimension, or the ratio of aspects depicted in the drawings may be different from those of an actual apparatus. Furthermore, designs thereof can be appropriately changed.

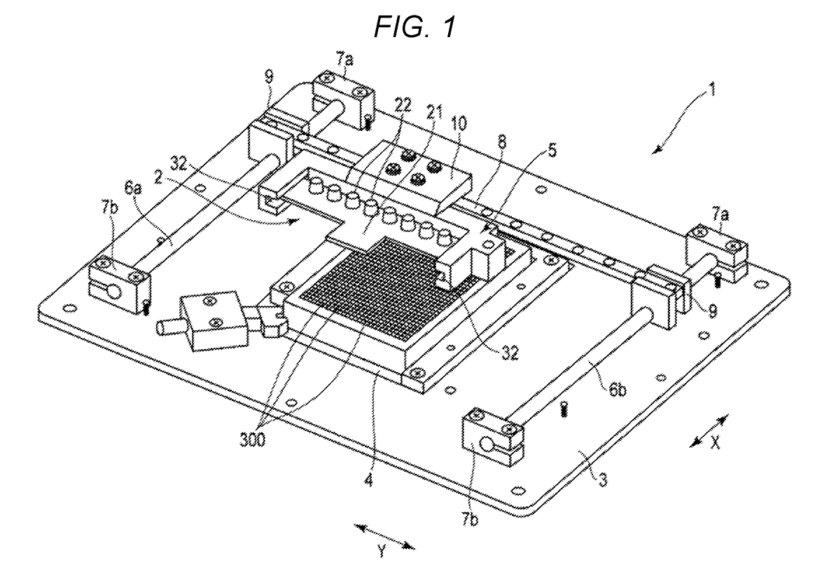

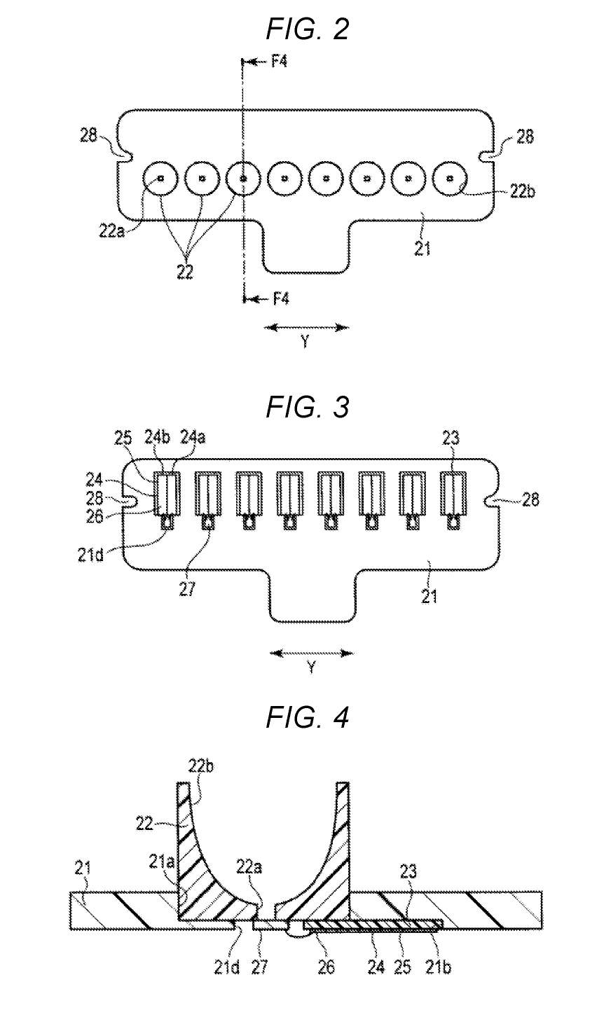

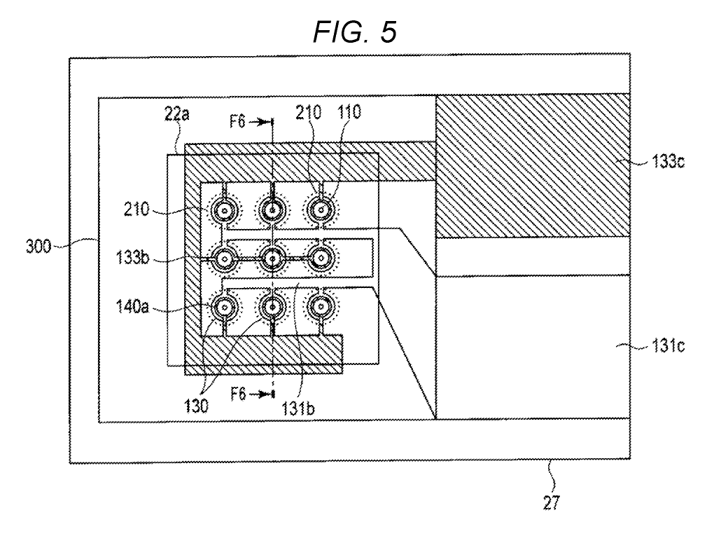

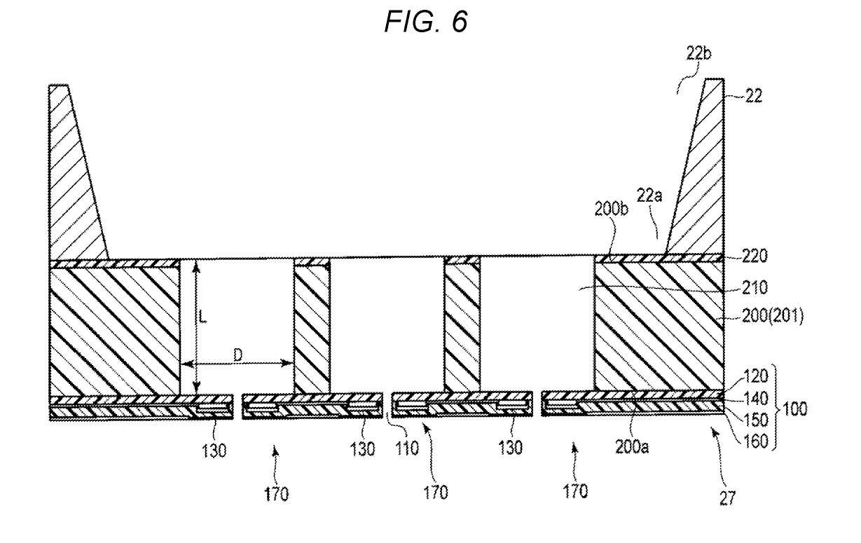

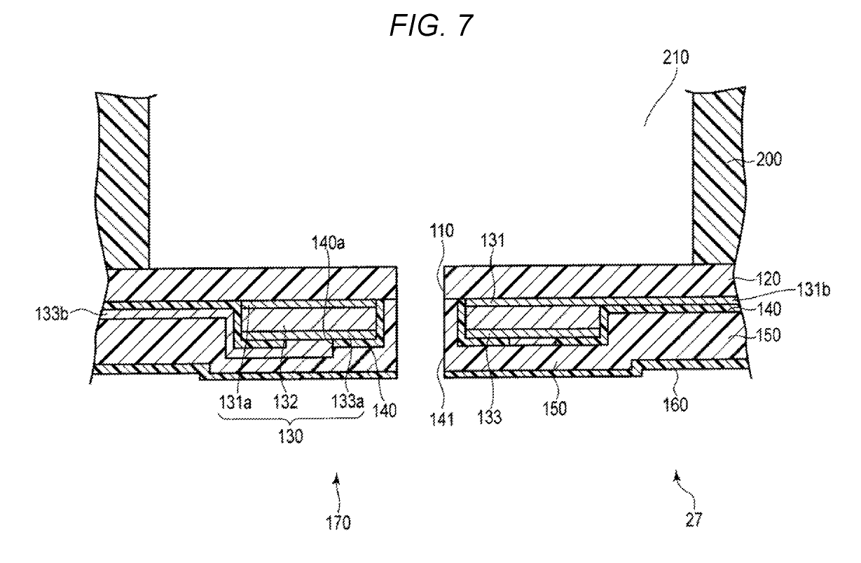

One example of the liquid medicine discharge device of the first embodiment will be described with reference to FIGS. 1 to 7. FIG. 1 is a perspective view of a liquid medicine dropping device 1 including a liquid medicine discharge device 2. FIG. 2 is a top view of the liquid medicine discharge device 2. FIG. 3 is a bottom view of the liquid medicine discharge device 2. FIG. 4 is a cross-sectional view taken along the line F4-F4 of FIG. 2. FIG. 5 is a plan view of a liquid medicine discharge array 27 of the liquid medicine discharge device 2. FIG. 6 is a cross-sectional view taken along the line F6-F6 of FIG. 5. FIG. 7 is a longitudinal sectional view of a peripheral structure of a nozzle 110 of the liquid medicine discharge device 2.

The liquid medicine dropping device 1 includes a base 3 having a shape of a rectangular flat plate, and a mounting module 5 which mounts the liquid medicine discharge device 2. In the example embodiment described herein, the liquid medicine is dropped onto a microplate 4 having 1536 holes is described. Here, a forward-and-rearward direction of the base 3 is referred to as an X direction, and a leftward-and-rightward direction of the base 3 is referred to as a Y direction. The X direction and the Y direction are orthogonal to each other.

The microplate 4 is fixed to the base 3. On the base 3, left and right X-direction guide rails 6a and 6b that extends in the X direction are provided on either side of the microplate 4. Both end portions of each of the X-direction guide rails 6a and 6b are fixed to fixing tables 7a and 7b which are installed to protrude on the base 3.

Between the X-direction guide rails 6a and 6b, a Y-direction guide rail 8 which extends in the Y direction is built. Both ends of the Y-direction guide rail 8 are respectively fixed to an X-direction moving table 9 which can slide in the X direction along the X-direction guide rails 6a and 6b.

On the Y-direction guide rail 8, a Y-direction moving table 10 is provided and can move the mounting module 5 in the Y direction along the Y-direction guide rail 8. On the Y-direction moving table 10, the mounting module 5 is mounted. The liquid medicine discharge device 2 is fixed to the mounting module 5. Accordingly, by combining an operation of the Y-direction moving table 10 in the Y direction along the Y-direction guide rail 8 and an operation of the X-direction moving table 9 in the X direction along X-direction guide rails 6a and 6b, the liquid medicine discharge device 2 can move at an arbitrary position in the X and Y directions which are orthogonal to each other.

The liquid medicine discharge device 2 includes a flat plate-shaped base member 21 having a rectangular shape. The base member 21 may be referred to as a board in some contexts. As illustrated in FIG. 2, on the front surface side of the base member 21, a plurality of liquid medicine holding containers 22 are aligned in a row in the Y direction. In the example embodiment described herein, eight liquid medicine holding containers 22 are described, but the number of liquid medicine holding containers 22 is not limited to eight. As illustrated in FIG. 4, the liquid medicine holding container 22 has a cylindrical shape of which an upper surface is open. On the front surface side of the base member 21, a recess portion 21a is formed at a position which corresponds to each of the liquid medicine holding containers 22.

A bottom portion of the liquid medicine holding container 22 adheres to and is fixed to the recess portion 21a. Furthermore, on the bottom portion of the liquid medicine holding container 22, an opening 22a, which is a liquid medicine outlet, is formed at the center position. An opening area of an upper surface opening 22b of the liquid medicine holding container 22 is larger than the opening area of the opening 22a of the liquid medicine outlet.

At both ends of the base member 21, mounting and fixing notches, also referred to as engaging recessed portions, 28 for mounting and fixing to the mounting module 5 are respectively formed. Two notches 28 of the base member 21 are formed in a semi-elliptical shape. The mounting and fixing notch 28 may have a semi-circular, a semi-ellipsoidal, or a triangular shape. In the example embodiment described herein, the shapes of two notches 28 are different from each other. Accordingly, the left and right shapes of the base member 21 are different from each other, and thus it is easy to confirm the orientation of the base member 21.

As illustrated in FIG. 3, on the rear surface side of the base member 21, the same number of electric substrates 23 as that of the liquid medicine holding containers 22 are aligned in a row in the Y direction. The electric substrate 23 is a rectangular flat plate member. On the rear surface side of the base member 21, as illustrated in FIG. 4, a rectangular recess portion 21b for mounting the electric substrate 23, and a liquid medicine discharge array portion opening 21d, which communicates with the recess portion 21b, are formed. A base end portion of the recess portion 21b extends to a position near the upper end portion in FIG. 3 (position near the right end portion in FIG. 4) of the base member 21. The tip end portion of the recess portion 21b extends to a position which overlaps a part of the liquid medicine holding container 22 as illustrated in FIG. 4. The electric substrate 23 is mounted and fixed to the recess portion 21b.

On the electric substrate 23, an electric substrate wiring 24 is patterning-formed on a surface opposite to a surface that adheres to and is fixed to the recess portion 21b. In the electric substrate wiring 24, two wiring patterns 24a and 24b which are respectively connected to a terminal portion 131c of a lower electrode 131 and a terminal portion 133c of an upper electrode 133 are formed, as illustrated in FIG. 5.

In one end portion of the electric substrate wiring 24, a control signal input terminal 25 for inputting a control signal from an external drive circuit is formed. In the other end portion of the electric substrate wiring 24, an electrode terminal connection portion 26 is provided. The electrode terminal connection portion 26 is a connection portion for connecting the lower electrode terminal portion 131c and the upper electrode terminal portion 133c which are formed in the liquid medicine discharge array 27, as illustrated in FIG. 5.

In the base member 21, a through-hole of the liquid medicine discharge array portion opening 21d is provided. The opening 21d in the liquid medicine discharge array portion is a rectangular opening as illustrated in FIG. 3, and overlaps with the recess portion 21a on the rear surface side of the base member 21.

On the lower surface of the liquid medicine holding container 22, the liquid medicine discharge array 27 illustrated in FIG. 5 adheres and fixed so that the liquid medicine discharge array 27 covers the opening 22a of the liquid medicine holding container 22. The liquid medicine discharge array 27 is disposed at a position which corresponds to the liquid medicine discharge array portion opening 21d in the base member 21.

As illustrated in FIG. 6, the liquid medicine discharge array 27 is formed as a stack of a nozzle plate 100 and a pressure chamber structure 200. The nozzle plate 100 includes a plurality of nozzles 110 for discharging the liquid medicine, a diaphragm 120, a driving element 130 serving as a driving unit, a protective film 150 serving as a protective layer, and a liquid repellent film 160. An actuator 170 has the diaphragm 120 and the driving element 130. In the example embodiment described herein, the actuator 170 has a piezoelectric element made of a lead-free material (i.e., non-lead material) that does not contain a lead component. As illustrated in FIG. 5, the plurality of nozzles 110 are arranged, for example, in a row of 3×3. The plurality of nozzles 110 are positioned on the inner side of the opening 22a of the liquid medicine outlet of the liquid medicine holding container 22.

The diaphragm 120 can be integrated with, for example, the pressure chamber structure 200. For example, when the pressure chamber structure 200 is manufactured on a silicon wafer 201 by a heat treatment in an oxygen atmosphere, a SiO₂ (silicon oxide) film is formed on the front surface of the silicon wafer 201. The diaphragm 120 may be the SiO₂ (silicon oxide) film of the front surface of the silicon wafer 201 formed by the heat treatment in the oxide atmosphere. The diaphragm 120 may be formed using a chemical vapor deposition (CVD) method by depositing the SiO₂ film on the front surface of the silicon wafer 201.

The film thickness of the diaphragm 120 is preferably within a range of 1 to 30 μm. For the diaphragm 120, a semiconductor material, such as SiN (silicon nitride) or the like, or Al₂O₃ (aluminum oxide) can also be used.

The driving element 130 is formed in each of the nozzles 110. The driving element 130 has an annular shape that surrounds the nozzle 110. The shape of the driving element 130 is not limited, and for example, may be a C shape made by cutting out a part of the circle. As illustrated in FIG. 7, the driving element 130 includes an electrode portion 131a of the lower electrode 131, and an electrode portion 133a of the upper electrode 133, sandwiching a piezoelectric film 132 which is a piezoelectric. The electrode portion 131a, the piezoelectric film 132, and the electrode portion 133a are coaxial to the nozzle 110, and have a circular pattern having the same diameter.

The lower electrodes 131 each include a plurality of circular electrode portions 131a coaxial with a corresponding circular nozzle 110. In FIG. 5, the electrode portion 131a of the lower electrode 131 and the electrode portion 133a of the upper electrode 133 overlap with each other as the driving element 130. As illustrated in FIG. 5, the lower electrode 131 includes a wiring portion 131b which connects the plurality of electrode portions 131a to one another, and the terminal portion 131c in the end portion of the wiring portion 131b.

The driving element 130 includes the piezoelectric film 132 formed of a piezoelectric material on the electrode portion 131a of the lower electrode 131. The piezoelectric film 132 uses KNN (a compound of KNbO₃ and NaNbO₃).

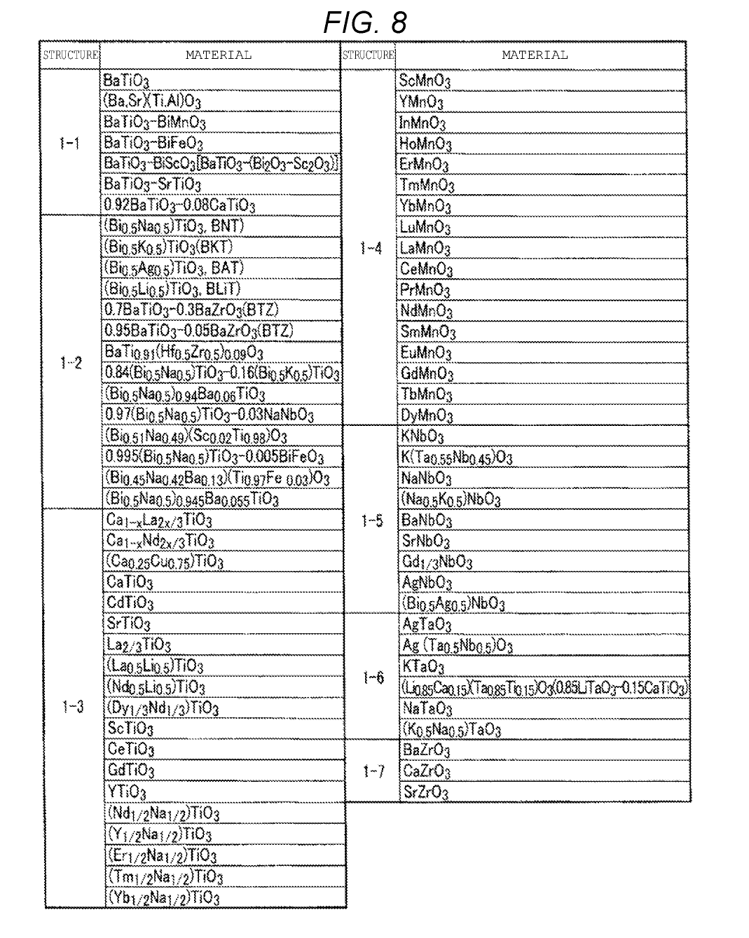

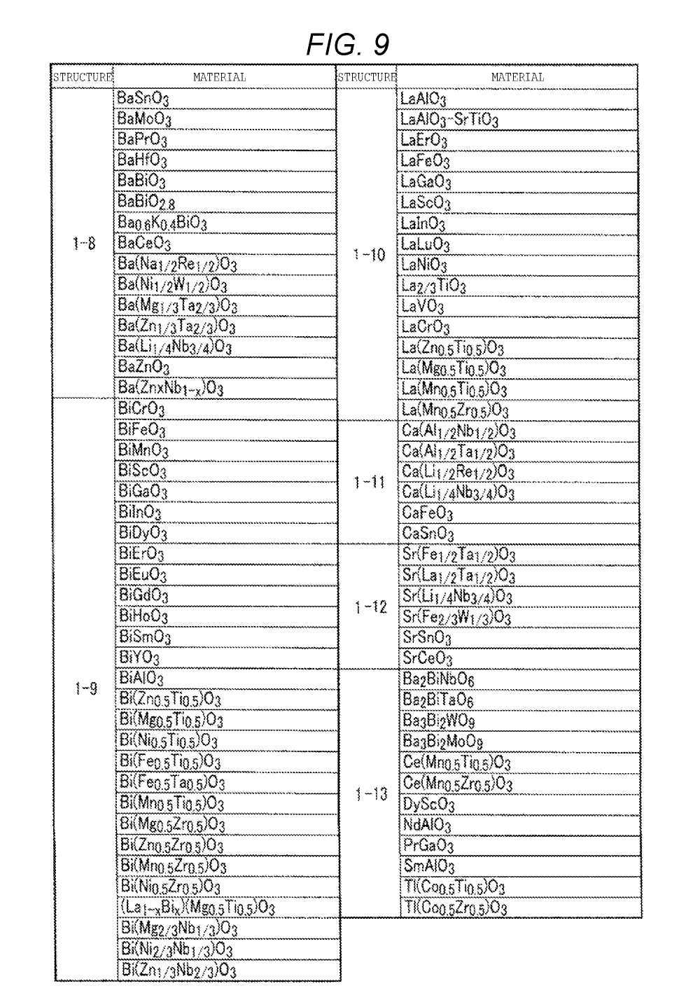

The piezoelectric film 132 is made of lead-free material. That is, piezoelectric film 132 does not contain a lead component. The lead-free material is, for example, one of a perovskite structure or a complex perovskite structure, an ilmenite structure, an oxide of a tungsten bronze structure, a A₂B₂O₇ (pyrochlore) perovskite structure, a layered structure oxide, and a bismuth layered structure ferroelectrics; ZnO; and AlN. Formulas [1-1], [1-2], [1-3], [1-4], [1-5], [1-6], and [1-7] of FIG. 8, and [1-8], [1-9], [1-10], [1-11], [1-12], and [1-13] of FIG. 9 illustrate the perovskite or the complex perovskite structures. The structure includes BaTiO₃, (Ba,Sr) (Ti,Al)O₃, BaTiO₃—BiMnO₃, BaTiO₃—BiFeO₃, BaTiO₃—BiScO₃ [BaTiO₃—(Bi₂O₃—Sc₂O₃)], BaTiO₃—SrTiO₃, 0.92BaTiO₃-0.08CaTiO₃, (Bi_{0.5}Na_{0.5})TiO₃, BNT), (Bi_{0.5}K_{0.5})TiO₃ (BKT) (Bi_{0.5}Ag_{0.5})TiO₃,BAT), (Bi_{0.5}Li_{0.5})TiO₃,BLiT) 0.7BaTiO₃-0.3BaZrO₃(BTZ), 0.95BaTiO₃-0.05BaZrO₃(BTZ), BaTi_{0.91} (Hf_{0.5}Zr_{0.5})0.09O₃, 0.84(Bi_{0.5}Na_{0.5})TiO₃-0.16(Bi_{0.5}K_{0.5})TiO₃, (Bi_{0.5}Na_{0.5})_{0.94}Ba_{0.06}TiO₃, 0.97(Bi_{0.5}Na_{0.5})TiO₃-0.03NaNbO₃, (Bi_{0.5}Na_{0.49}) (Sc_{0.02}Ti_{0.98})O₃, 0.995(Bi_{0.5}Na_{0.5})TiO₃-0.005BiFeO₃, (Bi_{0.45}Na_{0.42}Ba_{0.13})(Ti_{0.97}Fe_{0.03})O₃, (Bi_{0.5}Na_{0.5})_{0.945}Ba_{0.055}TiO₃, Ca₁₋ₓLa_{2x/3}TiO₃, Ca₁₋ₓNd_{2x/3}TiO₃, (Ca_{0.25}Cu_{0.75})TiO₃, CaTiO₃, CdTiO₃, SrTiO₃, La_{2/3}TiO₃, (La_{0.5}Li_{0.5})TiO₃, (Nd_{0.5}Li_{0.5})TiO₃, (Dy_{1/3}Nd_{1/3})TiO₃, ScTiO₃, CeTiO₃, GdTiO₃, YTiO₃, (Nd_{1/2}Na_{1/2})TiO₃, (Y_{1/2}Na_{1/2})TiO₃, (Er_{1/2}Na_{1/2})TiO₃, (Tm_{1/2}Na_{1/2})TiO₃, (Yb_{1/2}Na_{1/2})TiO₃, ScMnO₃, YMnO₃, InMnO₃, HoMnO₃, ErMnO₃, TmnMnO₃, YbMnO₃, LuMnO₃, LaMnO₃, CeMnO₃, PrMnO₃, NdMnO₃, SmnMnO₃, EuMnO₃, GdMnO₃, TbMnO₃, DyMnO₃, KNbO₃, K(Ta_{0.5}5Nb_{0.45})O₃, NaNbO₃, (Na_{0.5}K_{0.5})NbO₃, BaNbO₃, SrNbO₃, Gd_{1/3}NbO₃, AgNbO₃, (Bi_{0.5}Ag_{0.5})NbO₃, AgTaO₃, Ag(Ta_{0.5}Nb_{0.5})O₃, KTaO₃, (Li_{0.85}Ca_{0.15}) (Ta_{0.85}Ti_{0.15})O₃(0.85LiTaO₃-0.15CaTiO₃), NaTaO₃, (K_{0.5}Na_{0.5})TaO₃, BaZrO₃, CaZrO₃, SrZrO₃, BaSnO₃, BaMoO₃, BaPrO₃, BaHfO₃, BaBiO₃, BaBiO_{2.8}, Ba_{0.6}K_{0.4}BiO₃, BaCeO₃, Ba(Na_{1/2}Re_{1/2})O₃, Ba(Ni_{1/2}W_{1/2})O₃, Ba(Mg_{1/3}Ta_{2/3})O₃, Ba(Zn_{1/3}Ta_{2/3})O₃, Ba(Li_{1/4}Nb_{3/4})O₃, BaZnO₃, Ba(ZnₓNb₁₋ₓ)O₃, BiCrO₃, BiFeO₃, BiMnO₃, BiScO₃, BiGaO₃, BiInO₃, BiDyO₃, BiErO₃, BiEuO₃, BiGdO₃, BiHO₃, BiSmO₃, BiYO₃, BiAlO₃, Bi(Zn_{0.5}Ti_{0.5})O₃, Bi(Mg_{0.5}Ti_{0.5})O₃, Bi(Ni_{0.5}Ti_{0.5})O₃, Bi(Fe_{0.5}Ti_{0.5})O₃, Bi(Fe_{0.5}Ta_{0.5})O₃, Bi(Mn_{0.5}Ti_{0.5})O₃, Bi(Mg_{0.5}Zr_{0.5})O₃, Bi(Zn_{0.5}Zr_{0.5})O₃, Bi(Mn_{0.5}Zr_{0.5})O₃, Bi(Ni_{0.5}Zr_{0.5})O₃, (La₁₋ₓBiₓ)(Mg_{0.5}Ti_{0.5})O₃, Bi(Mg_{2/3}Nb_{1/3})O₃, Bi(Ni_{2/3}Nb_{1/3})O₃, Bi(Zn_{1/3}Nb_{2/3})O₃, LaAlO₃, LaAlO₃—SrTiO₃, LaErO₃, LaFeO₃, LaGaO₃, LaScO₃, LaInO₃, LaLuO₃, LaNiO₃, La₂/3TiO₃, LaVO₃, LaCrO₃, La(Zn_{0.5}Ti_{0.5})O₃, La(Mg_{0.5}Ti_{0.5})O₃, La(Mn_{0.5}Ti_{0.5})O₃, La(Mn_{0.5}Zr_{0.5})O₃, Ca(Al_{1/2}Nb_{1/2})O₃, Ca(Al_{1/2}Ta_{1/2})O₃, Ca(Li_{1/2}Re_{1/2})O₃, Ca(Li_{1/4}Nb_{3/4})O₃, CaFeO₃, CaSnO₃, Sr(Fe_{1/2}Ta_{1/2})O₃, Sr(La_{1/2}Ta_{1/2})O₃, Sr(Li_{1/4}Nb_{3/4})O₃, Sr(Fe_{2/3}W_{1/3})O₃, SrSnO₃, SrCeO₃, Ba₂BiNbO₆, Ba₂BiTaO₆, Ba₃Bi₂WO₉, Ba₃Bi₂MoO₉, Ce(Mn_{0.5}Ti_{0.5})O₃, Ce(Mn_{0.5}Zr_{0.5})O₃, DyScO₃, NdAlO₃, PrGaO₃, SmAlO₃, Tl(Co_{0.5}Ti_{0.5})O₃, and Tl(Co_{0.5}Zr_{0.5})O₃.

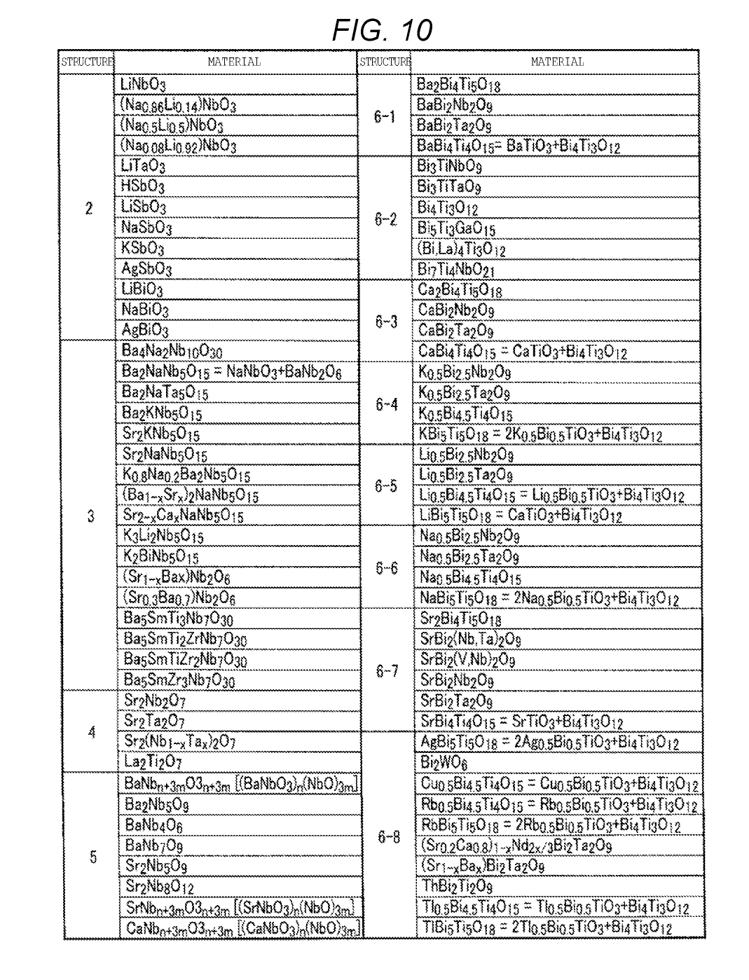

Structure group [2] of FIG. 10 illustrates the structure of the ilmenite structure. The structure group includes LiNbO₃, (Na_{0.86}Li_{0.14})NbO₃, (Na_{0.5}Li_{0.5})NbO₃, (Na_{0.09}Li_{0.92})NbO₃, LiTaO₃, HSbO₃, LiSbO₃, NaSbO₃, KSbO₃, AgSbO₃, LiBiO₃, NaBiO₃, and AgBiO₃. Structure group [3] of FIG. 10 includes Ba₄Na₂Nb₁₀O₃₀, Ba₂NaNb₅O₁₅═NaNbO₃+BaNb₂O₆, Ba₂NaTa₅O₁₅, Ba₂KNb₅O₁₅, Sr₂KNb₅O₁₅, Sr₂NaNb₅O₁₅, K_{0.8}Na_{0.2}Ba₂Nb₅O₁₅, (Ba₁₋ₓSrₓ)₂NaNb₅O₁₅, Sr₂₋ₓCaₓNaNb₅O₁₅, K₃Li₂Nb₅O₁₅, K₂BiNb₅O₁₅, (Sr₁₋ₓBaₓ)Nb₂O₆, (Sr_{0.3}Ba_{0.7})Nb₂O₆, Ba₅SmTi₃Nb₇O₃₀, Ba₅SmTi₂ZrNb₇O₃₀, Ba₅SmTiZr₂Nb₇O₃₀, and Ba₅SmZr₃Nb₇O₃₀. Structure group [4] of FIG. 10 illustrates a structure of the A₂B₂O₇ perovskite slab structure. This structure group includes Sr₂Nb₂O₇, Sr₂Ta₂O₇, Sr₂(Nb₁₋ₓTaₓ)₂O₇, and La₂Ti₂O₇. Structure group [5] of FIG. 10 illustrates a structure of the layered structure oxide. The structure group includes BaNbₙ₊₃ₘO₃ₙ₊₃ₘ[(BaNbO₃)ₙ(NbO)₃ₘ], Ba₂Nb₅O₉, BaNb₄O₆, BaNb₇O₉, Sr₂NbO₉, Sr₂Nb₈O₁₂, SrNbₙ₊₃ₘO₃ₙ₊₃ₘ[(SrNbO₃)ₙ(NbO)₃ₘ], and CaNbₙ₊₃ₘO₃ₙ₊₃ₘ[(CaNbO₃)ₙ(NbO)₃ₘ]. The formulas [6-1], [6-2], [6-3], [6-4], [6-5], [6-6], [6-7], and [6-8] of FIG. 10 illustrate a bismuth layered structure ferroelectrics. The structure group includes Ba₂Bi₄Ti₅O₁₈, BaBi₂Nb₂O₉, BaBi₂Ta₂O₉, BaBi₄Ti₄O₁₅═BaTiO₃+Bi₄Ti₃O₁₂, Bi₃TiNbO₉, Bi₃TiTaO₉, Bi₄Ti₃O₁₂, Bi₅Ti₃GaO₁₅, (Bi, La)₄Ti₃O₁₂, Bi₇Ti₄NbO₂₁, Ca₂Bi₄Ti₅O₁₈, CaBi₂Nb₂O₉, CaBi₂Ta₂O₉, CaBi₄Ti₄O₁=CaTiO₃+Bi₄Ti₃O₁₂, K_{0.5}Bi_{2.5}Nb₂O₉, K_{0.5}Bi_{2.5}Ta₂O₉, K_{0.5}Bi_{4.5}Ti₄O₁₅, KBi₅TiO₁₈=2K_{0.5}Bi_{0.5}TiO₃+Bi₄Ti₃O₁₂, Li_{0.5}Bi_{2.5}Nb₂O₉, Li_{0.5}Bi_{2.5}Ta₂O₉, Li_{0.5}Bi_{4.5}Ti₄O₁₅═Li_{0.5}Bi_{0.5}TiO₃+Bi₄Ti₃O₁₂, LiBi₅Ti₅O₁₈=CaTiO₃+Bi₄Ti₃O₁₂, Na_{0.5}Bi_{2.5}Nb₂O₉, Na_{0.5}Bi_{2.5}Ta₂O₉, Na_{0.5}Bi_{4.5}Ti₄O₁₅, NaBi₅Ti₅O₁₈=2Na_{0.5}Bi_{0.5}TiO₃+Bi₄Ti₃O₁₂, Sr₂Bi₄Ti₅O₁₈, SrBi₂(Nb,Ta)₂O₉, SrBi₂(V,Nb)₂O₉, SrBi₂Nb₂O₉, SrBi₂Ta₂O₉, SrBi₄Ti₄O₁₅=SrTiO₃+Bi₄Ti₃O₁₂, AgBi₅Ti₅O₁₈=2Ag_{0.5}Bi_{0.5}TiO₃+Bi₄Ti₃O₁₂, Bi₂WO₆, Cu_{0.5}Bi_{4.5}Ti₄O₁₅═Cu_{0.5}Bi_{0.5}TiO₃+Bi₄Ti₃O₁₂, Rb_{0.5}Bi_{4.5}Ti₄O₁₅═Rb_{0.5}Bi_{0.5}TiO₃+Bi₄Ti₃O₁₂, RbBi₅Ti₅O₁₈=2Rb_{0.5}Bi_{0.5}TiO₃+Bi₄Ti₃O₁₂, (Sr_{0.2}Ca_{0.8})₁₋ₓNd_{2x/3}Bi₂Ta₂O₉, (Sr₁₋ₓBaₓ)Bi₂Ta₂O₉, ThBi₂Ti₂O₉, Tl_{0.5}Bi_{4.5}Ti₄O₁₅═Tl_{0.5}Bi_{0.5}TiO₃+Bi₄Ti₃O₁₂, and TlBi₅Ti₅O₁₈=2Tl_{0.5}Bi_{0.5}TiO₃+Bi₄Ti₃O₁₂. Furthermore, a compound in which a composition ratio of the material is changed, a compounding of two or more of the materials, and a complex composition compound obtained by adding a small amount of elements to the material or the compound of two or more of the materials, are also included.

The piezoelectric film 132 generates polarization in the thickness direction. When applying the electric field in the direction of the polarization to the piezoelectric film 132, the piezoelectric film 132 expands and contracts in a direction orthogonal to the electric field. In other words, the piezoelectric film 132 contracts or expands in the direction orthogonal to the film thickness.

The upper electrode 133 of the driving element 130 is coaxial to the nozzle 110 on the piezoelectric film 132, and has an annular shape which is the same as that of the piezoelectric film 132. As illustrated in FIG. 7, the upper electrode 133 includes a wiring portion 133b which connects the plurality of electrode portions 133a to one another, and the terminal portions 133c in the end portion of the wiring portion 133b as illustrated in FIG. 5. When a constant voltage is applied to the upper electrode 133, a voltage control signal is applied to the lower electrode 131.

The lower electrode 131 is formed having a thickness of 0.5 μm by staking Ti (titanium) and Pt (platinum), for example, by a sputtering method. The film thickness of the lower electrode 131 is in a range of approximately 0.01 to 1 μm. For the lower electrode 131, other materials, such as Ni (nickel), Cu (copper), Al (Aluminum), Ti (Titanium), W (tungsten), Mo (molybdenum), Au (gold), or SrRuO₃ (strontium ruthenium oxide) can be used. The lower electrode 131 can be used by stacking various types of metal.

The upper electrode 133 is formed of a Pt thin film. As other electrode materials of the upper electrode 133, it is also possible to use Ni, Cu, Al, Ti, W, Mo, Au, and SrRuO₃. As another film forming method, it is also possible to use evaporation or plating. The upper electrode 133 can also be used by stacking various types of metal.

The nozzle plate 100 includes an insulating film 140 which insulates the lower electrode 131 from the upper electrode 133. The insulating film 140 covers a circumferential edge of the electrode portion 131a, the piezoelectric film 132, and the electrode portion 133a in a region proximate to the driving element 130. The insulating film 140 covers the wiring portion 131b of the lower electrode 131. The insulating film 140 covers the diaphragm 120 in a region proximate to the wiring portion 133b of the upper electrode 133. The insulating film 140 includes a contact portion 140a which electrically connects the electrode portion 133a and the wiring portion 133b of the upper electrode 133 to each other.

The nozzle plate 100 includes the protective film 150. The protective film 150 includes a cylindrical liquid medicine passage portion 141 which communicates with the nozzle 110 of the diaphragm 120.

The nozzle plate 100 includes the liquid repellent film 160 that covers the protective film 150. The liquid repellent film 160 can be formed, for example, by spin-coating a silicone resin that repels the liquid medicine. The liquid repellent film 160 can also be formed of other materials having characteristics of repelling the liquid medicine, such as a fluororesin.

The pressure chamber structure 200 includes a warp reduction film 220 which is a warp reduction layer, on the surface opposite to the diaphragm 120. The pressure chamber structure 200 includes a pressure chamber 210 that penetrates the warp reduction film 220 and reaches the position of the diaphragm 120, and thus communicates with the nozzle 110. The pressure chamber 210 is formed, for example, in a circular shape which is positioned coaxially to the nozzle 110.

However, in the example embodiment described herein, the pressure chamber 210 includes an opening which communicates with the opening 22a of the liquid medicine holding container 22. It is preferable to make a size L in the depth direction greater than a size D in the width direction of the opening of the pressure chamber 210. By making the size L in the depth direction greater than the size D in the width direction, the pressure applied to the liquid medicine in the pressure chamber 210 by the oscillation of the diaphragm 120 of the nozzle plate 100 is delayed in escaping to the liquid medicine holding container 22.

In the pressure chamber structure 200, a side on which the diaphragm 120 of the pressure chamber 210 is disposed is referred to as a first surface 200a, and a side on which the warp reduction film 220 is disposed is referred as a second surface 200b. On the warp reduction film 220 side of the pressure chamber structure 200, the liquid medicine holding container 22 adheres by, for example, an epoxy adhesive. The pressure chamber 210 communicates with the opening 22a of the liquid medicine holding container 22 in the opening on the warp reduction film 220 side. The opening area of the opening 22a of the liquid medicine holding container 22 is larger than a total area of the pressure chambers 210 formed in the liquid medicine discharge array 27 communicating with the opening 22a of the liquid medicine holding container 22. Therefore, all of the pressure chambers 210 formed on the liquid medicine discharge array 27 communicate with the opening 22a of the liquid medicine holding container 22.

The diaphragm 120 is deformed in the thickness direction by operations of the driving elements 130. The liquid medicine discharge device discharges the liquid medicine supplied to the nozzle 110 by the pressure change generated in the pressure chamber 210 by the deformation of the diaphragm 120.

Next, an action of the above-described configuration will be described. The liquid medicine discharge device 2 is fixed to the mounting module 5 of the liquid medicine dropping device 1. When the liquid medicine discharge device 2 is attached to the mounting module 5, the liquid medicine discharge device 2 is inserted into a slit 32 of the mounting module 5 from the front surface opening side of the slit 32 of the mounting module 5.

When the liquid medicine discharge device 2 is used, at first, a predetermined amount of liquid medicine is supplied to the liquid medicine holding container 22 by a pipettor (not illustrated) or the like, from the upper surface opening 22b of the liquid medicine holding container 22. The liquid medicine is held on the inner surface of the liquid medicine holding container 22. The opening 22a of the bottom portion of the liquid medicine holding container 22 communicates with the liquid medicine discharge array 27. The liquid medicine held by the liquid medicine holding container 22 fills each of the pressure chambers 210 via the opening 22a of the bottom surface of the liquid medicine holding container 22.

The liquid medicine held in the liquid medicine discharge device 2 contains, for example, any of low molecular weight compound, fluorogenic reagent, protein, antibody, nucleic acid, blood plasma, bacteria, blood corpuscle, and cell. Amain solvent of the liquid medicine (i.e., a material having the highest weight ratio or volume ratio) is generally, water, glycerin, or dimethyl sulfoxide.

In this manner, the voltage control signal is input to the control signal input terminal 25 of the electric substrate wiring 24. The voltage control signal is sent to the terminal portion 131c of the lower electrode 131 and the terminal portion 133c of the upper electrode 133 from the electrode terminal connection portion 26 of the electric substrate wiring 24. At this time, by deforming the diaphragm 120 and changing the capacity of the pressure chamber 210 in accordance with the applying of the voltage control signal to the driving element 130, the liquid medicine from the nozzle 110 of the liquid medicine discharge array 27 is discharged as the liquid medicine droplets. In addition, a predetermined amount of liquid is dropped to each of well opening 300 of the microplate 4 from the nozzle 110.

Typical methods of controlling the pressure of the pressure chamber 210, include a thermal jet method and a piezojet method. The actuator 170 in the example embodiment described herein adopts a piezojet method.

In the thermal jet method, the liquid medicine is heated and boiled by a thermal energy generated from a thin film heater which is the actuator, and the liquid medicine is discharged at the pressure. At this time, since the temperature of the thin film heater becomes equal to or greater than 300° C., it is preferable that, in the low molecular weight compound, fluorogenic reagent, protein, antibody, nucleic acid, blood plasma, bacteria, blood corpuscle, and cell, which are contained in the liquid medicine, the quality is not changed and the heat resistance is high, even when the temperature becomes equal to or greater than 300° C.

In the piezojet method, the actuator includes the driving element 130 which is the piezoelectric element and the diaphragm 120. The diaphragm 120 is deformed by the piezoelectric element deformed by the voltage control signal. Accordingly, by controlling the pressure of the liquid medicine in the pressure chamber 210, the liquid medicine is discharged. Therefore, the liquid medicine is discharged without being heated.

When the liquid medicine discharge device 2 is used, the amount of one liquid droplet discharged from the nozzle 110 is in a rage of 2 to 5 picoliters. Therefore, by controlling the number of droplets, it is possible to control the amount of the liquid ejected into each of the well openings 300 of the microplate 4 on the order of picoliters (pL) to microliters (μL). Here, the liquid medicine held by each of the well openings 300 of the microplate 4 is any solvent containing cell, blood corpuscle, bacteria, blood plasma, antibody, DNA, nucleic acid, and protein.

In the example embodiment described herein, the actuator 170 includes the piezoelectric element made of a lead-free material. The piezoelectric element made of the lead-free material has typically has lesser piezoelectric characteristics compared to the piezoelectric elements made of PZT (Pb(Zr,Ti)O₃: lead zirconate titanate) or other materials containing a lead component. Therefore, with the piezoelectric element made of the lead-free material, the displacement amount of the diaphragm 120 during the driving is typically smaller than that provided by a piezoelectric element made of PZT, and thus, the amount of one liquid droplet is smaller.

Here, as illustrated in FIG. 5, the plurality of nozzles 110 (e.g., nine in the example embodiment described herein) are disposed above one well opening 300 of the microplate 4. In this manner, by disposing the plurality of nozzles 110 above one well opening 300, it is possible to complete the ejections of a necessary amount of liquid medicine during a shorter period of time even with the piezoelectric element having low piezoelectric characteristics. Therefore, similar to the microplate 4 having 1536 holes, it is also possible to complete the ejections of the necessary amount of liquid medicine during a shorter period of time into all of the well openings 300 of the microplate 4 having a large number of wells. The main body of the used liquid medicine discharge device 2 is disposable.

Therefore, in the liquid medicine discharge device 2 having the above-described configuration, the main body of the used liquid medicine discharge device 2 can be disposed of as it is. The actuator 170 of the liquid medicine discharge device 2 includes the piezoelectric element made of a lead-free material, disposing of the main body of the used liquid medicine discharge device 2 is environmentally safer.

In addition, for the use in medical and biological fields, the liquid medicine discharge device 2 are attached, detached and exchanged several times daily, and the time duration of use is extremely short. Therefore, the piezoelectric element of the lead-free material in the actuator 170 having less durability compared to that of PZT (Pb(Zr,Ti)O₃:lead zirconate titanate) can sufficiently satisfy performance requirements in the disposable liquid medicine discharge device 2.

In the example embodiment described herein, the driving element 130 serving the driving unit has a circular shape, but the shape of the driving unit is not limited to a circular shape. The shape of the driving unit may be, for example, a rhombus shape or an elliptical shape. In addition, the shape of the pressure chamber 210 is also not limited to a circular shape, and may be a rhombus shape, an elliptical shape, or a rectangular shape.

In the example embodiment described herein, the nozzle 110 is disposed at the center of the driving element 130, but the position of the nozzle 110 is not particularly limited as long as the liquid medicine of the pressure chamber 210 can be discharged from the nozzle 110. For example, the nozzle 110 may not be formed in the region of the driving element 130, and may be formed on an outer side of the driving element 130. If the nozzle 110 is disposed on the outer side of the driving element 130, it is not necessary to perform patterning with respect to the nozzle 110 penetrating the plurality of film materials of the driving element 130. Likewise, the plurality of film materials of the driving element 130 do not necessarily perform the opening patterning process to be performed at the position which corresponds to the nozzle 110, the nozzle 110 can be formed only by patterning the diaphragm 120 and the protective film 150, and the patterning becomes easy.

According to the above-described example embodiments, it is possible to provide an environmentally safe disposable liquid medicine discharge device, and a liquid medicine dropping device. In this context, “medicine” refers to a compound used for the treatment and/or amelioration of a disease condition or its symptoms. In this context, “medicine” also refers to a compound being researched for use in the treatment and/or amelioration of a disease condition or its symptoms.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid medicine discharge device, comprising:
a nozzle plate having a nozzle from which a liquid medicine can be discharged;
a pressure chamber structure having an outlet on a first surface side and an inlet on a second surface side and a pressure chamber in fluid communication with the nozzle via the outlet on the first side;
a liquid holding container on the second surface and in fluid communication with the pressure chamber via the inlet on the second surface; and
an actuator configured to cause the liquid medicine to be ejected from the nozzle by changing pressure in the pressure chamber and including a piezoelectric element formed of a lead-free material.

2. The liquid medicine discharge device according to claim 1, wherein the lead-free material has a structure selected from a perovskite structure, a complex perovskite structure, an ilmenite structure, an oxide of a tungsten bronze structure, a pyrochlore perovskite structure, a layered structure oxide, and a bismuth layered structure ferroelectrics.

3. The liquid medicine discharge device according to claim 1, wherein the lead-free material is selected from BaTiO₃, (Ba, Sr) (Ti, Al)O₃, BaTiO₃—BiMnO₃, BaTiO₃—BiFeO₃, BaTiO₃—BiScO₃ [BaTiO₃—(Bi₂O₃—Sc₂O₃)], BaTiO₃—SrTiO₃, 0.92BaTiO₃-0.08CaTiO₃, (Bi_{0.5}Na_{0.5})TiO₃,BNT), (Bi_{0.5}K_{0.5})TiO₃(BKT), (Bi_{0.5}Ag_{0.5})TiO₃,BAT) (Bi_{0.5}Li_{0.5})TiO₃,BLiT), 0.7BaTiO₃-0.3BaZrO₃(BTZ), 0.95BaTiO₃-0.5BaZrO₃(BTZ), BaTi_{0.91} (Hf_{0.5}Zr_{0.5}) 0.09O₃, 0.84(Bi_{0.5}Na_{0.5})TiO₃-0.16(Bi_{0.5}K_{0.5})TiO₃, (Bi_{0.5}Na_{0.5})_{0.94}Ba_{0.06}TiO₃, 0.97(Bi_{0.5}Na_{0.5})TiO₃-0.03NaNbO₃, (Bi_{0.5}Na_{0.49}) (Sc_{0.02}Ti_{0.98})O₃, 0.995(Bi_{0.5}Na_{0.5})TiO₃-0.005BiFeO₃, (Bi_{0.45}Na_{0.42}Ba_{0.13}) (Ti_{0.97}Fe_{0.03})O₃, (Bi_{0.5}Na_{0.5})_{0.945}Ba_{0.055}TiO₃, Ca₁₋ₓLa_{2x/3}TiO₃, Ca₁₋ₓNd_{2x/3}TiO₃, (Ca_{0.25}Cu_{0.75})TiO₃, CaTiO₃, CdTiO₃, SrTiO₃, La_{2/3}TiO₃, (La_{0.5}Li_{0.5})TiO₃, (Nd_{0.5}Li_{0.5})TiO₃, (Dy_{1/3}Nd_{1/3})TiO₃, ScTiO₃, CeTiO₃, GdTiO₃, YTiO₃, (Nd_{1/2}Na_{1/2})TiO₃, (Y_{1/2}Na_{1/2})TiO₃, (Er_{1/2}Na_{1/2})TiO₃, (Tm_{1/2}Na_{1/2})TiO₃, (Yb_{1/2}Na_{1/2})TiO₃, ScMnO₃, YMnO₃, InMnO₃, HoMnO₃, ErMnO₃, TmnMnO₃, YbMnO₃, LuMnO₃, LaMnO₃, CeMnO₃, PrMnO₃, NdMnO₃, SmnMnO₃, EuMnO₃, GdMnO₃, TbMnO₃, DyMnO₃, KNbO₃, K(Ta_{0.5}5Nb_{0.45})O₃, NaNbO₃, (Na_{0.5}K_{0.5})NbO₃, BaNbO₃, SrNbO₃, Gd_{1/3}NbO₃, AgNbO₃, (Bi_{0.5}Ag_{0.5})NbO₃, AgTaO₃, Ag(Ta_{0.5}Nb_{0.5})O₃, KTaO₃, (Li_{0.85}Ca_{0.15}) (Ta_{0.85}Ti_{0.15})O₃(0.85LiTaO₃-0.15CaTiO₃), NaTaO₃, (K_{0.5}Na_{0.5})TaO₃, BaZrO₃, CaZrO₃, SrZrO₃, BaSnO₃, BaMoO₃, BaPrO₃, BaHfO₃, BaBiO₃, BaBiO_{2.8}, Ba_{0.6}K_{0.4}BiO₃, BaCeO₃, Ba(Na_{1/2}Re_{1/2})O₃, Ba(Ni_{1/2}W_{1/2})O₃, Ba(Mg_{1/3}Ta_{2/3})O₃, Ba(Zn_{1/3}Ta_{2/3})O₃, Ba(Li_{1/4}Nb_{3/4})O₃, BaZnO₃, Ba(ZnₓNb₁₋ₓ)O₃, BiCrO₃, BiFeO₃, BiMnO₃, BiScO₃, BiGaO₃, BiInO₃, BiDyO₃, BiErO₃, BiEuO₃, BiGdO₃, BiHO₃, BiSmO₃, BiYO₃, BiAlO₃, Bi(Zn_{0.5}Ti_{0.5})O₃, Bi(Mg_{0.5}Ti_{0.5})O₃, Bi(Ni_{0.5}Ti_{0.5})O₃, Bi(Fe_{0.5}Ti_{0.5})O₃, Bi(Fe_{0.5}Ta_{0.5})O₃, Bi(Mn_{0.5}Ti_{0.5})O₃, Bi(Mg_{0.5}Zr_{0.5})O₃, Bi(Zn_{0.5}Zr_{0.5})O₃, Bi(Mn_{0.5}Zr_{0.5})O₃, Bi(Ni_{0.5}Zr_{0.5})O₃, (La₁₋ₓBiₓ) (Mg_{0.5}Ti_{0.5})O₃, Bi(Mg_{2/3}Nb_{1/3})O₃, Bi(Ni_{2/3}Nb_{1/3})O₃, Bi(Zn_{1/3}Nb_{2/3})O₃, LaAlO₃, LaAlO₃—SrTiO₃, LaErO₃, LaFeO₃, LaGaO₃, LaScO₃, LaInO₃, LaLuO₃, LaNiO₃, La_{2/3}TiO₃, LaVO₃, LaCrO₃, La(Zn_{0.5}Ti_{0.5})O₃, La(Mg_{0.5}Ti_{0.5})O₃, La(Mn_{0.5}Ti_{0.5})O₃, La(Mn_{0.5}Zr_{0.5})O₃, Ca(Al_{1/2}Nb_{1/2})O₃, Ca(Al_{1/2}Ta_{1/2})O₃, Ca(Li_{1/2}Re_{1/2})O₃, Ca(Li_{1/4}Nb_{3/4})O₃, CaFeO₃, CaSnO₃, Sr(Fe_{1/2}Ta_{1/2})O₃, Sr(La_{1/2}Ta_{1/2})O₃, Sr(Li_{1/4}Nb_{3/4})O₃, Sr(Fe_{2/3}W_{1/3})O₃, SrSnO₃, SrCeO₃, Ba₂BiNbO₆, Ba₂BiTaO₆, Ba₃Bi₂WO₉, Ba₃Bi₂MoO₉, Ce(Mn_{0.5}Ti_{0.5})O₃, Ce(Mn_{0.5}Zr_{0.5})O₃, DyScO₃, NdAlO₃, PrGaO₃, SmAlO₃, Tl(Co_{0.5}Ti_{0.5})O₃, and Tl(Co_{0.5}Zr_{0.5})O₃.

4. The liquid medicine discharge device according to claim 1, wherein the actuator is deformed by a voltage control signal from an external drive circuit and causes a volume change in the pressure chamber.

5. A liquid medicine dispensing device, comprising:
a mounting module to which a liquid medicine discharge device according to claim 1 is attached as a disposable unit;
a first moving table that can move the mounting module in first direction; and
a second moving table that can move the mounting module in second direction perpendicular to the first direction.

6. The liquid medicine discharge device according to claim 1, further comprising:
a plurality of nozzles disposed within a second surface side opening of the liquid holding container, the plurality of nozzles being in fluid communication with the liquid holding container via the pressure chamber structure.

7. The liquid medicine discharge device according to claim 6, wherein an upper surface opening of the liquid holding container is larger than the second surface side opening.

8. A liquid medicine discharge array, comprising:
a nozzle plate having a plurality of nozzles from which a liquid medicine can be discharged, each nozzle in the plurality of nozzles having a pressure chamber associated therewith;
a liquid holding container in fluid communication with the pressure chambers; and
a plurality of actuators having a diaphragm and a driving element, each actuator in the plurality of actuators being configured to cause the liquid medicine to be ejected from the nozzle by changing pressure in the pressure chamber associated with each nozzle in the plurality of nozzles, wherein
each actuator includes a piezoelectric film made of a lead-free material.

9. The liquid medicine discharge array according to claim 8, wherein the lead-free material has a structure selected from a perovskite structure, a complex perovskite structure, an ilmenite structure, an oxide of a tungsten bronze structure, a pyrochlore perovskite structure, a layered structure oxide, and a bismuth layered structure ferroelectrics.

10. The liquid medicine discharge array according to claim 8, wherein the lead-free material is selected from BaTiO₃, (Ba, Sr) (Ti, Al)O₃, BaTiO₃—BiMnO₃, BaTiO₃—BiFeO₃, BaTiO₃—BiScO₃ [BaTiO₃—(Bi₂O₃—Sc₂O₃)], BaTiO₃—SrTiO₃, 0.92BaTiO₃-0.08CaTiO₃, (Bi_{0.5}Na_{0.5})TiO₃,BNT), (Bi_{0.5}K_{0.5})TiO₃ (BKT), (Bi_{0.5}Ag_{0.5})TiO₃,BAT) (Bi_{0.5}Li_{0.5})TiO₃,BLiT), 0.7BaTiO₃-0.3BaZr₃(BTZ), 0.95BaTiO₃-0.05BaZrO₃(BTZ), BaTi_{0.91} (Hf_{0.5}Zr_{0.5})0.09O₃, 0.84(Bi_{0.5}Na_{0.5})TiO₃-0.16(Bi_{0.5}K_{0.5})TiO₃, (Bi_{0.5}Na_{0.5})_{0.94}Ba_{0.06}TiO₃, 0.97(Bi_{0.5}Na_{0.5})TiO₃-0.03NaNbO₃, (Bi_{0.5}Na_{0.49}) (Sc_{0.02}Ti_{0.98})O₃, 0.995(Bi_{0.5}Na_{0.5})TiO₃-0.005BiFeO₃, (Bi_{0.45}Na_{0.42}Ba_{0.13}) (Ti_{0.97}Fe_{0.03})O₃, (Bi_{0.5}Na_{0.5})_{0.945}Ba_{0.055}TiO₃, Ca₁₋ₓLa_{2x/3}TiO₃, Ca₁₋ₓNd_{2x/3}TiO₃, (Ca_{0.25}Cu_{0.75})TiO₃, CaTiO₃, CdTiO₃, SrTiO₃, La_{2/3}TiO₃, (La_{0.5}Li_{0.5})TiO₃, (Nd_{0.5}Li_{0.5})TiO₃, (Dy_{1/3}Nd_{1/3})TiO₃, ScTiO₃, CeTiO₃, GdTiO₃, YTiO₃, (Nd_{1/2}Na_{1/2})TiO₃, (Y_{1/2}Na_{1/2})TiO₃, (Er_{1/2}Na_{1/2})TiO₃, (Tm_{1/2}Na_{1/2})TiO₃, (Yb_{1/2}Na_{1/2})TiO₃, ScMnO₃, YMnO₃, InMnO₃, HoMnO₃, ErMnO₃, TmnMnO₃, YbMnO₃, LuMnO₃, LaMnO₃, CeMnO₃, PrMnO₃, NdMnO₃, SmnMnO₃, EuMnO₃, GdMnO₃, TbMnO₃, DyMnO₃, KNbO₃, K(Ta_{0.5}5Nb_{0.45})O₃, NaNbO₃, (Na_{0.5}K_{0.5})NbO₃, BaNbO₃, SrNbO₃, Gd_{1/3}NbO₃, AgNbO₃, (Bi_{0.5}Ag_{0.5})NbO₃, AgTaO₃, Ag(Ta_{0.5}Nb_{0.5})O₃, KTaO₃, (Li_{0.85}Ca_{0.15})(Ta_{0.85}Ti_{0.15})O₃(0.85LiTaO₃-0.15CaTiO₃), NaTaO₃, (K_{0.5}Na_{0.5}) TaO₃, BaZrO₃, CaZrO₃, SrZrO₃, BaSnO₃, BaMoO₃, BaPrO₃, BaHfO₃, BaBiO₃, BaBiO₂0.8, Ba_{0.6}K_{0.4}BiO₃, BaCeO₃, Ba(Na_{1/2}Re_{1/2})O₃, Ba(Ni_{1/2}W_{1/2})O₃, Ba(Mg_{1/3}Ta_{2/3})O₃, Ba(Zn_{1/3}Ta_{2/3})O₃, Ba(Li_{1/4}Nb_{3/4})O₃, BaZnO₃, Ba(ZnₓNb₁₋ₓ)O₃, BiCrO₃, BiFeO₃, BiMnO₃, BiScO₃, BiGaO₃, BiInO₃, BiDyO₃, BiErO₃, BiEuO₃, BiGdO₃, BiHoO₃, BiSmO₃, BiYO₃, BiAlO₃, Bi(Zn_{0.5}Ti_{0.5})O₃, Bi(Mg_{0.5}Ti_{0.5})O₃, Bi(Ni_{0.5}Ti_{0.5})O₃, Bi(Fe_{0.5}Ti_{0.5})O₃, Bi(Fe_{0.5}Ta_{0.5})O₃, Bi(Mn_{0.5}Ti_{0.5})O₃, Bi(Mg_{0.5}Zr_{0.5})O₃, Bi(Zn_{0.5}Zr_{0.5})O₃, Bi(Mn_{0.5}Zr_{0.5})O₃, Bi(Ni_{0.5}Zr_{0.5})O₃, (La₁₋ₓBiₓ) (Mg_{0.5}Ti_{0.5})O₃, Bi(Mg_{2/3}Nb_{1/3})O₃, Bi(Ni_{2/3}Nb_{1/3})O₃, Bi(Zn_{1/3}Nb_{2/3})O₃, LaAlO₃, LaAlO₃—SrTiO₃, LaErO₃, LaFeO₃, LaGaO₃, LaScO₃, LaInO₃, LaLuO₃, LaNiO₃, La_{2/3}TiO₃, LaVO₃, LaCrO₃, La(Zn_{0.5}Ti_{0.5})O₃, La(Mg_{0.5}Ti_{0.5})O₃, La(Mn_{0.5}Ti_{0.5})O₃, La(Mn_{0.5}Zr_{0.5})O₃, Ca(Al_{1/2}Nb_{1/2})O₃, Ca(Al_{1/2}Ta_{1/2})O₃, Ca(Li_{1/2}Re_{1/2})O₃, Ca(Li_{1/4}Nb_{3/4})O₃, CaFeO₃, CaSnO₃, Sr(Fe_{1/2}Ta_{1/2})O₃, Sr(La_{1/2}Ta_{1/2})O₃, Sr(Li_{1/4}Nb_{3/4})O₃, Sr(Fe_{2/3}W_{1/3})O₃, SrSnO₃, SrCeO₃, Ba₂BiNbO₆, Ba₂BiTaO₆, Ba₃Bi₂WO₉, Ba₃Bi₂MoO₉, Ce(Mn_{0.5}Ti_{0.5})O₃, Ce(Mn_{0.5}Zr_{0.5})O₃, DyScO₃, NdAlO₃, PrGaO₃, SmAlO₃, Tl(Co_{0.5}Ti_{0.5})O₃, and Tl(Co_{0.5}Zr_{0.5})O₃.

11. The liquid medicine discharge array according to claim 8, wherein each of the actuator is deformed by a voltage control signal from an external drive circuit and causes a volume change in the pressure chamber.

12. The liquid medicine discharge array according to claim 8, wherein each of the plurality of nozzles is in fluid communication with a bottom surface opening of the liquid holding container via the associated pressure chamber.

13. The liquid medicine discharge array according to claim 12, wherein an upper surface opening of the liquid holding container is larger than the bottom surface opening.

14. A liquid medicine dispensing device, comprising:
a liquid discharge device comprising:
a nozzle plate having a nozzle from which a liquid medicine can be discharged;
a pressure chamber structure having an outlet on a first surface side and an inlet on a second surface side and a pressure chamber in fluid communication with the nozzle via the outlet on the first side;
a liquid medicine holding container on the second surface and in fluid communication with the pressure chamber via the inlet on the second surface;
an actuator configured to cause the liquid medicine to be ejected from the nozzle by changing pressure in the pressure chamber and including a piezoelectric element formed of a lead-free material;
a base on which a microplate can be disposed; and
a mounting module having engaging recessed portions for mounting the liquid discharge device, the mounting module being configured to move the liquid discharge device along a guide rail in a plane parallel to the base, wherein
the liquid discharge device is detachable from the mounting module.

15. The liquid medicine dispensing device according to claim 14, wherein the microplate is selected from a 96 well microplate, a 384 well microplate, a 1,536 well microplate, a 3,456 well microplate, and a 6,144 well microplate.

16. The liquid medicine dispensing device according to claim 14, wherein the lead-free material has a structure selected from a perovskite structure, a complex perovskite structure, an ilmenite structure, an oxide of a tungsten bronze structure, a pyrochlore perovskite structure, a layered structure oxide, and a bismuth layered structure ferroelectrics.

17. The liquid medicine dispensing device according to claim 14, wherein the lead-free material is selected from BaTiO₃, (Ba, Sr) (Ti, Al)O₃, BaTiO₃—BiMnO₃, BaTiO₃—BiFeO₃, BaTiO₃—BiScO₃ [BaTiO₃—(Bi₂O₃—Sc₂O₃)], BaTiO₃—SrTiO₃, 0.92BaTiO₃-0.08CaTiO₃, (Bi_{0.5}Na_{0.5})TiO₃,BNT), (Bi_{0.5}K_{0.5})TiO₃ (BKT), (Bi_{0.5}Ag_{0.5})TiO₃,BAT), (Bi_{0.5}Li_{0.5})TiO₃,BLiT), 0.7BaTiO₃-0.3BaZrO₃(BTZ), 0.95BaTiO₃-0.05BaZrO₃(BTZ), BaTi_{0.91} (Hf_{0.5}Zr_{0.5}) 0.09O₃, 0.84(Bi_{0.5}Na_{0.5})TiO₃-0.16(Bi_{0.5}K_{0.5})TiO₃, (Bi_{0.5}Na_{0.5})_{0.94}Ba_{0.06}TiO₃, 0.97(Bi_{0.5}Na_{0.5})TiO₃-0.03NaNbO₃, (Bi_{0.5}Na_{0.49}) (Sc_{0.02}Ti_{0.98})O₃, 0.995(Bi_{0.5}Na_{0.5})TiO₃-0.005BiFeO₃, (Bi_{0.45}Na_{0.42}Ba_{0.13}) (Ti_{0.97}Fe_{0.03})O₃, (Bi_{0.5}Na_{0.5})_{0.94}5Ba_{0.055}TiO₃, Ca₁₋ₓLa_{2x/3}TiO₃, Ca₁₋ₓNd_{2x/3}TiO₃, (Ca_{0.25}Cu_{0.75})TiO₃, CaTiO₃, CdTiO₃, SrTiO₃, La_{2/3}TiO₃, (La_{0.5}Li_{0.5})TiO₃, (Nd_{0.5}Li_{0.5})TiO₃, (Dy_{1/3}Nd_{1/3})TiO₃, ScTiO₃, CeTiO₃, GdTiO₃, YTiO₃, (Nd_{1/2}Na_{1/2})TiO₃, (Y_{1/2}Na_{1/2})TiO₃, (Er_{1/2}Na_{1/2})TiO₃, (Tm_{1/2}Na_{1/2})TiO₃, (Yb_{1/2}Na_{1/2})TiO₃, ScMnO₃, YMnO₃, InMnO₃, HoMnO₃, ErMnO₃, TmMnO₃, YbMnO₃, LuMnO₃, LaMnO₃, CeMnO₃, PrMnO₃, NdMnO₃, SmMnO₃, EuMnO₃, GdMnO₃, TbMnO₃, DyMnO₃, KNbO₃, K(Ta_{0.5}Nb_{0.45})O₃, NaNbO₃, (Na_{0.5}K_{0.5})NbO₃, BaNbO₃, SrNbO₃, Gd_{1/3}NbO₃, AgNbO₃, (Bi_{0.5}Ag_{0.5})NbO₃, AgTaO₃, Ag(Ta_{0.5}Nb_{0.5})O₃, KTaO₃, (Li_{0.85}Ca_{0.15}) (Ta_{0.85}Ti_{0.15})O₃(0.85LiTaO₃-0.15CaTiO₃), NaTaO₃, (K_{0.5}Na_{0.5})TaO₃, BaZrO₃, CaZrO₃, SrZrO₃, BaSnO₃, BaMoO₃, BaPrO₃, BaHfO₃, BaBiO₃, BaBiO_{2.8}, Ba_{0.6}K_{0.4}BiO₃, BaCeO₃, Ba(Na_{1/2}Re_{1/2})O₃, Ba(Ni_{1/2}W_{1/2})O₃, Ba(Mg_{1/3}Ta_{2/3})O₃, Ba(Zn_{1/3}Ta_{2/3})O₃, Ba(Li_{1/4}Nb_{3/4})O₃, BaZnO₃, Ba(ZnₓNb₁₋ₓ)O₃, BiCrO₃, BiFeO₃, BiMnO₃, BiScO₃, BiGaO₃, BiInO₃, BiDyO₃, BiErO₃, BiEuO₃, BiGdO₃, BiHoO₃, BiSmO₃, BiYO₃, BiAlO₃, Bi(Zn_{0.5}Ti_{0.5})O₃, Bi(Mg_{0.5}Ti_{0.5})O₃, Bi(Ni_{0.5}Ti_{0.5})O₃, Bi(Fe_{0.5}Ti_{0.5})O₃, Bi(Fe_{0.5}Ta_{0.5})O₃, Bi(Mn_{0.5}Ti_{0.5})O₃, Bi(Mg_{0.5}Zr_{0.5})O₃, Bi(Zn_{0.5}Zr_{0.5})O₃, Bi(Mn_{0.5}Zr_{0.5})O₃, Bi(Ni_{0.5}Zr_{0.5})O₃, (La₁₋ₓBiₓ) (Mg_{0.5}Ti_{0.5})O₃, Bi(Mg_{2/3}Nb_{1/3})O₃, Bi(Ni_{2/3}Nb_{1/3})O₃, Bi(Zn_{1/3}Nb_{2/3})O₃, LaAlO₃, LaAlO₃—SrTiO₃, LaErO₃, LaFeO₃, LaGaO₃, LaScO₃, LaInO₃, LaLuO₃, LaNiO₃, La_{2/3}TiO₃, LaVO₃, LaCrO₃, La(Zn_{0.5}Ti_{0.5})O₃, La(Mg_{0.5}Ti_{0.5})O₃, La(Mn_{0.5}Ti_{0.5})O₃, La(Mn_{0.5}Zr_{0.5})O₃, Ca(Al_{1/2}Nb_{1/2})O₃, Ca(Al_{1/2}Ta_{1/2})O₃, Ca(Li_{1/2}Re_{1/2})O₃, Ca(Li_{1/4}Nb_{3/4})O₃, CaFeO₃, CaSnO₃, Sr(Fe_{1/2}Ta_{1/2})O₃, Sr(La_{1/2}Ta_{1/2})O₃, Sr(Li_{1/4}Nb_{3/4})O₃, Sr(Fe_{2/3}W_{1/3})O₃, SrSnO₃, SrCeO₃, Ba₂BiNbO₆, Ba₂BiTaO₆, Ba₃Bi₂WO₉, Ba₃Bi₂MoO₉, Ce(Mn_{0.5}Ti_{0.5})O₃, Ce(Mn_{0.5}Zr_{0.5})O₃, DyScO₃, NdAlO₃, PrGaO₃, SmAlO₃, Tl(Co_{0.5}Ti_{0.5})O₃, and Tl(Co_{0.5}Zr_{0.5})O₃.

18. The liquid medicine dispensing device according to claim 14, wherein the actuator is deformed by a voltage control signal from an external drive circuit and causes a volume change in the pressure chamber.

19. The liquid medicine dispensing device according to claim 14, further comprising:
a plurality of nozzles disposed within a second surface side opening of the liquid holding container, the plurality of nozzles being in fluid communication with the liquid medicine holding container via the pressure chamber structure.

20. The liquid medicine dispensing device according to claim 19, wherein an upper surface opening of the liquid medicine holding container is larger than the second surface side opening.
